(19) United States
(12) Patent Application Publication
(10) Pub. No.: US 2011/0260945 A1
(43) Pub. Date: Oct. 27, 2011

(54) Coating Composition and Article Using the Same

(76) Inventor: Fumio Karasawa, Tokyo (JP)

(21) Appl. No.: 12/671,934

(22) PCT Filed: Aug. 19, 2008
(86) PCT No.: PCT/US08/73584

§ 371 Date: Feb. 3, 2010

(30) Foreign Application Priority Data
Aug. 3, 2007 (DE) 10 207 036 644.4

(51) Int. Cl. H01Q 1/40; B32B 3/02; H01B 3/30; F21V 15/00; C09D 127/20; H05K 1/00

(52) U.S. Cl. 343/873; 524/520; 174/254; 174/258; 174/110 SR; 362/362; 428/206

(57) ABSTRACT

To provide a coating composition which is excellent in water resistance, insulating properties and ultraviolet degradation resistance, and is also excellent in transparency of a coating film formed after coating.

The present disclosure relates to a coating composition and an article using the same.

### BACKGROUND

A coating composition using a fluoropolymer has conventionally been known, and is widely used because of the performance properties such as waterproofing.

JP Publ. No. 6-116531 describes a fluorine-based polymer-containing topcoating material for aqueous coating film, which is used to impart waterproofing properties to architectural structures such as a roof, a veranda, and a bath. This aqueous topcoating material is a composite waterproofing layer comprising layer of waterproofing coating film comprising an aqueous vinyl acetate-based copolymer dispersion solution (component A) and a cement binder and a coating film layer comprising a component A, a fluoropolymer dispersion solution, and a pigment.

JP Publ. Nos. 57-34107 and 57-34108 describe a fluorine-containing copolymer capable of being dissolved in an organic solvent used to exhibit waterproofing properties in a baking coating material and other coating materials.

Furthermore, JP Publ. No. 8-217993 describes a fluid repellant coating material comprising particles of a low molecular weight ethylene tetrafluoride resin and a binder resin, which is useful for coating on an automobile body and tableware.

Furthermore, JP Publ. No. 5-152067 describes an EL (electroluminescent) light emitting element in which a light emitting portion is sealed with a protective layer, the protective layer comprising a waterproofing coating layer formed of a fluorine-based monomer coated on the entire perimeter of the light emitting portion, and a waterproofing layer formed of material sold under the trade designation “TEFLON” or a silicone tube.

On the other hand, JP Publ. No. 2003-114304 discloses an antireflective film comprising a transparent substrate and at least a single light scattering layer formed on the transparent substrate, which is not directly involved in a coating composition which imparts waterproofing properties. JP Publ. No. 2003-114304 describes a light scattering layer containing translucent fine particles and a translucent resin and a difference in a refractive index between the translucent fine particles and the translucent resin of 0.02 or more and 0.15 or less. Polystrene beads also are included as the translucent fine particles and bis(4-methacryloylthiophenyl)sulfide is included as the translucent resin. It is described that the difference in the refractive index is adjusted so as to obtain a preferable light scattering angle.

The use of LEDs (light emitting diodes) has been increasing. For example, LEDs have increasingly been used in luminescent traffic signal devices. Because the traffic signal devices already use large and strong housing to maintain high waterproofing properties, the electric bulbs and fluorescent lamps used in these devices have been replaced with LEDs to achieve energy savings and reduce maintenance cost. LED use in an automobile red tail lights also has being increasing.

Although an LED itself is in the form of a portable chip, in luminescent devices such as traffic signal devices, a large-sized pedestal is required to install the LED chip, and a large-sized transparent housing or cover is required to provide waterproofing capability. Furthermore, it is expected that in the future, LEDs used in a lighting devices in for example the lighting of an express highway and exterior lighting could be turned on during the night to achieve further energy savings. Taking account of these respects and problems of the above traffic signal device, it is preferable to provide a luminescent device such as a traffic signal device or an exterior lighting system, which are durable, not bulky, and are waterproof. Additionally, it is desirable that, after coating an apparatus with a waterproofing coating composition, the inside of the apparatus is transparent for ease in subsequent repairing.

To solve these problems, it is considered to seal an LED used as a luminescent device with a waterproofing coating material so as to impart a waterproofing function to the LED. However, a conventional waterproofing coating material has insufficient insulating properties and is inferior in ultraviolet degradation resistance, which limits its use outdoors.

### SUMMARY

Thus, it is desired to provide a coating composition having excellent water resistance, insulating properties, and ultraviolet degradation resistance, which seals a conductive portion of wiring, electric contacts, and electric wire to provide devices, such as luminescent devices, which are durable, not bulky, and waterproof.

The present disclosure includes the following aspects.

In one embodiment, a coating composition comprising a fluoropolymer A, a fluoropolymer B and a solvent is provided wherein the fluoropolymer A is soluble in the solvent, and the fluoropolymer B is granular and is insoluble in the solvent.

In another embodiment an article comprising an article, and a coating layer formed of the coating composition wherein the coating composition is used to seal at least a conductive portion of the article is provided.

As used herein, “conductive portion” includes any electrically connecting means used to constitute the article of the present disclosure, as is easily understood by the following description. Examples of suitable electrically connecting means include, but are not limited to, electric contact such as electric/electronic circuit, electric wiring, conductor wire, flip chip, and bump. In the present disclosure, antenna is also defined as “conductive portion”.

Also, as used herein, “functional element” includes optional parts which can actively or passively function in an electronic device and other apparatuses. Typical examples of the functional device include, but are not limited to, a light emitting device such an LED chip, a semiconductor element such as an IC (integrated circuit) chip or an LSI (lightening imaging sensor) chip, a capacitor (condenser), a reactor, a inductor, and a resistor.

### BRIEF DESCRIPTION OF THE DRAWINGS

FIG. 1 is a plan view (A), and a sectional view (B) which show one example of a circuit board comprising an LED chip installed therein according to the present disclosure;

FIG. 2 is a plan view (A) and a sectional view (B) which show another example of a circuit board comprising an LED chip installed therein according to the present disclosure;

FIG. 3 is a plan view (A) and a sectional view (B) which show another example of a circuit board comprising an LED chip installed therein according to the present disclosure;

FIG. 4 is a perspective view (A) of a substrate used in a water resistance test; and

FIG. 5 a top view (A) and a side view of a substrate using a bullet-shaped LED including long pins.

### DETAILED DESCRIPTION

In the case of sealing a conductive portion such as electric/electronic circuit, electric wiring, electric contact, or electric wire, a coating composition which can easily form a sealing layer (hereinafter referred to as a “coating layer” in the present disclosure) is provided. The coating composition can also impart excellent water resistance, insulating properties and durability, particularly ultraviolet degradation resistance, which are derived from physical properties of the coating layer, to the resulting sealed article.

Also, the present disclosure contains solvent insoluble fluoropolymer particles and therefore can properly improve the viscosity without shortening a working life up to drying of a coating composition. Therefore, it becomes easy to perform thick coating of the coating composition and a thick transparent coating membrane can be formed by a single coating operation.

Also, this coating composition is easily prepared, for example, by dissolving a fluoropolymer in a solvent and dispersing fluoropolymer particles and therefore can be coated by simple coating means such as brush coating or dip coating. Thus, this coating composition can be easily coated even on a medium having an irregular surface, for example, a circuit board comprising an LED chip mounted on a surface, or a semiconductor substrate comprising an LSI chip installed therein.

Furthermore, since the resulting coating layer has excellent water resistance, insulating properties and durability, particularly ultraviolet degradation resistance, it is possible to provide various articles utilizing these excellent characteristics, for example, in an LED device of an outdoor advertising device, a traffic signal device, a electroluminescence device, other electric device, a lighting system, and a coated electric wire. These articles can stably maintain excellent characteristics for a long period even when exposed to ultraviolet light, or wind and rain. For example, it is considered that the article of the present disclosure can be continuously used for about 10 years without causing deterioration of characteristics and damage. As a matter of course, since the coating composition of the present disclosure contains a fluoropolymer as a base, it is possible to impart other good characteristics: such as excellent water resistance, insulating properties, and durability (particularly ultraviolet degradation resistance and heat resistance and oil resistance or staining resistance) to the resulting article.

Furthermore, even if the article is not used in water, the article of the present disclosure has very excellent water resistance (Japanese Industrial Standard C0920 (corresponding to IEC60529) protection class 7 or higher class (immersion-proof type): level in which immersion of water in an amount enough to exert an adverse influence even when immersed in water in a depth of 15 cm to 1 m for 30 minutes), and thus it becomes possible to use under conditions closer to the use in water. For example, in the case of a luminescent device requiring a DC power supply such as the devices using an LED, resistance to water, namely, water resistance is important as compared with conventional luminescent devices that use, for example, an electric bulb or a fluorescent lamp, which require an AC power supply. In the case of a device using an AC power supply, even if some of the insulating material is somewhat damaged by water, a large amount of oxygen and hydrogen are not generated as a result of water electrolysis. To the contrary, in the case of a device using a DC power supply, if the insulating material is damaged there is a fear that oxygen and hydrogen may be generated by the electrolysis of water. Furthermore, wirings made of copper, lead, or silver used for connection tend to be ionized and dissolved in water. However, since the coating composition of the present disclosure is remarkably excellent in water resistance, when the coating composition is applied to an LED and the resulting LED is placed outdoors, or placed in a location where an LED is likely to be wetted, a location where humidity is high or the position where dew condensation may occur, the LED does not deteriorate and it does not become impossible to use. Since durability, particularly ultraviolet degradation resistance, is added to these features, market expansion can be expected in the future in other articles of the present disclosure and portions thereof (for example, surface of woods, surface of paper materials, surface of cloth materials, surface of flooring materials).

The present disclosure provides a coating composition, and an article, for example, an LED device, various electric devices, and an antenna, in which the conductive portion such as wiring, electric contact or electric wire is sealed by coating with the coating composition.

In one embodiment, a coating composition is prepared by dispersing particles of a fluoropolymer (fluoropolymer B) which is insoluble in a solvent, into a coating composition comprising substantially a fluoropolymer (A) which is soluble in a solvent and the solvent containing the fluoropolymer dissolved therein. The term “fluoropolymer which is soluble in a solvent” means a fluoropolymer in which a mixture of a solvent and a solute made of a fluoropolymer exhibits a stable, single and uniform liquid state in a macroscopic state. Also, the term “fluoropolymer which is insoluble in a solvent” means a fluoropolymer which is dispersed in a solvent. A difference between a refractive index of the fluoropolymer A and a refractive index of the fluoropolymer B is preferably less than 0.15, since it can provide a transparent coating layer.

The fluoropolymer A used in the present disclosure may exhibit various characteristics, such as the molecular structure and fluorine atoms contained in the molecule that are useful. The fluoropolymer A is, for example, substantially transparent and does not exert an adverse influence on light transmission. Also, fluoropolymer A has, as particular characteristics, water resistance, insulating properties, durability including ultraviolet degradation resistance, heat resistance and oil resistance (staining resistance). Furthermore, the fluoropolymer A of the present disclosure can be easily dissolved in a solvent and therefore can be easily applied by coating. Particularly, since fluoropolymer A and the solvent used in the present disclosure does not necessarily need to be heated to dissolve the fluoropolymer, not only are the handling properties noticeably improved, but also the range of the use of fluoropolymer A is increased. In the prior art, it is required to increase film strength by using additives in the coating composition such as a reaction catalyst or a crosslinking agent to introduce a crosslinked structure so as to form a fluororesin coating. However, in the present disclosure, it is not necessary to use such additives which can react to crosslink the fluoropolymer.

In one embodiment of the present disclosure, the fluoropolymer A is not specifically limited as long as it has excellent characteristics described above and also sufficiently exhibits these characteristics in the resulting coating composition and article, and includes various fluorine-based reins and fluorine-based rubbers. Also, the molecular weight of the fluoropolymer A can vary within a wide range, but is commonly about 10,000 or more. When the molecular weight is less than 10,000, it may become impossible to form a resin film after drying the coating composition. The molecular weight of the fluoropolymer A is preferably within a range from about 50,000 to 200,000, and more preferably from about 50,000 to 150,000. When the fluoropolymer A has a high molecular weight, the above-described characteristics are exhibited more satisfactorily. The molecular weight of the fluoropolymer A means a molecular weight obtained by ASTM D4001-93 (2006): Standard Test Method for Determination of Weight-Average Molecular Weight of Polymers by Light Scattering.

Fluoropolymer A includes partially fluorinated and perfluorinated polymers including fluoroplastics and fluoroelastomers. Examples of fluoropolymer A of the present disclosure include, but are not limited to, FEVE—(fluoroethylene-alkyl vinyl ether alternative copolymer), PVDF—(polyvinylidene fluoride) and THV-based fluoropolymers. These fluoropolymers may be used alone or in combination.

The FEVE-based fluoropolymer is, for example, a fluorine-containing copolymer which contains olefin, cyclohexyl vinyl ether, alkyl vinyl ether, and hydroxyalkyl vinyl ether as essential constituent components, wherein the copolymer may be partially fluorinated or perfluorinated. In such a copolymer, the contents of olefin, cyclohexyl vinyl ether, alkyl vinyl ether and hydroxyalkyl vinyl ether are respectively from 40 to 60 mol % (mole %), 5 to 45 mol %, 3 to 15 mol % and 0 to 30 mol %. As the olefin, a perhaloolefin, chlorotrifluoroethylene or tetrafluoroethylene may be used. An example of the FEVE-based fluoropolymer is a fluorine-containing copolymer containing, as essential constituent components, fluoroolefin, cyclohexyl vinyl ether, and glycidyl vinyl ether.

The VDF-based fluoropolymer may be a rubber (elastomer)-based fluoropolymer or a plastic. When the VDF-based fluoropolymer is a rubber-based fluoropolymer, it includes for example, a copolymer of vinylidene fluoride (VDF), tetrafluoroethylene (TFE), and propylene; a fluororubber comprising a copolymer of VDF and hexafluoropropylene (HFP); and a fluororubber comprising a copolymer of VDF, HFP, and TFE. When the VDF-based fluoropolymer is a plastic-based fluoropolymer, it includes for example, VDF polymer and VDF-TFE copolymer.

The fluoropolymer A may be a fluoropolymer containing at least HFP and VDF. Such a fluoropolymer is typically a binary fluoropolymer comprising HFP and VDF, or a fluoropolymer comprising at least TFE, HFP and VDF, for example a ternary fluoropolymer comprising the above monomers (e.g., THV). Among these THV-based fluoropolymers, some THV-based fluoropolymers are easily dissolved in a solvent and have excellent characteristics such as water resistance, insulating properties and ultraviolet degradation resistance. Furthermore, the fluoropolymer can be coated on the non-flat surface of a circuit board by a simple method such as brush coating or dip coating and a thick coating film can be easily formed by multiple coating.

In the above binary or ternary fluoropolymer, a composition ratio of TFE, HFP, and VDF of the fluoropolymer can vary within a wide range. However, when the fluoropolymer is used for the purpose of sealing an article, a fluoropolymer having excellent fluidity, excellent processability and low permeability of moisture is desired. Also, a fluoropolymer having proper crystallinity and a proper melting point is preferable so as to seal the article. When the fluoropolymer is used for LEDs, light transmission properties are also important so as to maintain an intensity of light to be emitted from an LED. In one embodiment, fluoropolymer A contains about 36 to 72% by weight of TFE, about 0 to 56% by weight of HFP and about 30 to 65% by weight of VDF is preferable. When the content of TFE increases deviating from such a composition ratio, the resulting fluoropolymer becomes opaque and transparency deteriorates. Also, fluoropolymer A having a preferable composition ratio as disclosed above has the following advantages, namely, it maintains chemical resistance similar to that of PTFE (polytetrafluoroethylene), has a low substance permeability, a crystallinity of about 30%, which cannot be attained by a conventional fluororubber, and flexibility. A fluoropolymer, such a fluoropolymer A, can easily follow the deformation when applied to a flexible circuit board because of the flexibility and also defects such as cracks do not occur. Therefore, it can be advantageously used to produce a down-sized electronic device with a complicated arrangement of constituent components.

For reference, a THV-based fluoropolymer containing about 36 to 72% by weight of TFE, about 0 to 56% by weight of HFP and about 8 to 45% by weight of VDF was compared with a conventional fluororesin, and the following results were obtained.

TABLE 1

| Characteristics | THV | PTFE | PFA | FEP | PVDF | ETFE |
|---|---|---|---|---|---|---|
| Water resistance | Excellent | Excellent | Excellent | Excellent | Excellent | Excellent |
| Weatherability | Excellent | Excellent | Excellent | Excellent | Excellent | Excellent |
| Light transmission | Excellent | Fail | Good | Good | Excellent | Excellent |
| properties | | | | | | |
| Processability | Excellent | Fail | Pass | Pass | Good | Good |
| (Melting point) | (120-180° C.) | (327° C.) | (290-310° C.) | (255-260° C.) | (160-175° C.) | (260-270° C.) |
| Adhesion | Excellent | Pass | Pass | Pass | Good | Good |
| properties | | | | | | |

Note)
Evaluation criteria: Excellent > Good > Pass > Fail
PFA: perfluoroalkoxyethylene
FEP: perfluoroethylene-propylene copolymer
PVDF: polyvinyldene fluoride
ETFE: ethylene-tetrafluoroethylene copolymer

THV-based fluoropolymer is commercially available, for example, from Dyneon Co., Oakdale, Minn. sold under the trade designation of “DYNEON” THV 220, “DYNEON” THV 415, “DYNEON” THV 500. In the present disclosure, THV220 is particularly useful and has such characteristics: melting point of 120° C., glass transition point at 5° C., flame retardancy V-0 (in accordance with UL-94), low moisture vapor transmission, and a refractive index of 1.36.

The coating composition comprises a solvent and a proper amount of fluoropolymer A dissolved in the solvent. The solvent is not specifically limited as long as the solvent can easily dissolve fluoropolymer A and does not exert an adverse influence on the characteristics of the resulting coating composition and article. The solvent is preferably a ketone-based solvent, an ester-based solvent, a furan-based solvent, or a polar solvent. These solvents may be used alone or in combination.

Examples of solvents that are suitable, such as those that dissolve THV-based fluoropolymers include ketone-based, ester-based, and polar solvents. Examples of the ketone-based solvent include: acetone (dimethyl ketone), MEK (methyl ethyl ketone), diethyl ketone, and MIBK (methyl isobutyl ketone). Examples of the ester-based solvent include methyl acetate, ethyl acetate, and butyl acetate. An example of the furan-based solvent includes THF (tetrahydrofuran). An example of the polar solvent includes NMP (N-methyl-2-pyrrolidone).

Examples of solvents that are suitable to dissolve the PVDF-based fluoropolymer include: polar solvents such as NMP(N-methyl-2-pyrrolidone), DMAC (dimethylacetamide), DMSO (dimethyl sulfoxide), and DMF (N,N-dimethylformamide); and a mixed solvent of butyl acetate, MIBK (methyl isobutyl ketone), and toluene.

In dissolving fluoropolymer A in the solvents described above, the amount of fluoropolymer A can vary within a wide range according to fluoropolymer A, the solvent, and the details of the coating composition. Fluoropolymer A can be used in the amount of about 25% by weight or less, and preferably from about 5 to 20% by weight, based on the weight of the coating composition excluding a fluoropolymer which is insoluble in the solvent (fluoropolymer B). More preferably, fluoropolymer A can be used in the amount of about 10 to 15% by weight. When the amount of fluoropolymer A is less than 1% by weight, a composition having a viscosity suited for coating cannot be obtained and the coating film cannot exhibit various characteristics derived from the fluoropolymer. To the contrary, when the amount of fluoropolymer A is more than 20% by weight, a composition having viscosity suited for coating cannot be obtained and only a composition having a low strength and inferior characteristics is obtained.

In the coating composition of the present disclosure, a fluoropolymer (fluoropolymer B), which is granular and insoluble in the solvent, is added and dispersed in a solution of fluoropolymer A and solvent. The addition of fluoropolymer B makes it possible to adjust to the viscosity, which in turn, enables a thick coating to be applied through a single coating operation. Additionally, the coating composition may be designed to achieve optimal coating thickness and appropriate drying time. For example, if the concentration of fluoropolymer A was increased to achieve a thicker coating, without adding the fluoropolymer B, the viscosity of the resulting composition would rapidly increase, however, the resulting composition cannot be easily coated, and is more difficult to handle because of the drying time is too short.

The amount of particles of fluoropolymer B is preferably from 50 to 150% in terms of the dry weight of particles of the fluoropolymer B to the dry weight of particles of the fluoropolymer A. When the percentage of fluoropolymer B particles is too small, the effect of the addition of fluoropolymer B is not exerted. On the other hand, when the percentage of fluoropolymer B is too large, voids are formed because of the insufficient amount of fluoropolymer A, which serves as a continuous matrix after the drying of the coating composition.

Examples of fluoropolymer B, include: PTFE-based particles, THV-based particles, PFA-based particles, FEP-based particles, ETFE-based particles, VDF-based particles, PCTFE (polychlorotrifluoroethylene)-based particles, and ECTFE (ethylene-chlorotrifluoroethylene copolymer)-based particles, and combinations thereof. Also, the difference between the refractive index of fluoropolymer A and the refractive index of fluoropolymer B is less than 0.15. Similarity of the refractive index between fluoropolymers A and B can allow for transparency of the coating film after drying the coating composition. The refractive index of fluoropolymer A and the refractive index of fluoropolymer B is not specifically limited, but the difference between them is less than 0.15. For example, when fluoropolymer A is a THV-based polymer (with a refractive index of about 1.36) and a large amount of PTFE particles (refractive index: 1.35) and TFE particles is added to the fluoropolymer A and solvent solution, one can achieve a dried coating composition with good transparency. The refractive index is measured by ISO 489 (1999): Plastics-Determination of refractive index.

The particle size of fluoropolymer B is not specifically limited, but is commonly from 1 to 1,000 μm. When the particle size is too small, it becomes difficult to achieve thick coatings easily. On the other hand, when the particle size is too large, it may become difficult to achieve transparency and smoothness of the film coating. The particles of fluoropolymer B, preferably have a high transparency so as to allow transparency of the coating film obtained from the coating composition. Transparency can be obtained by decreasing the particle size in the case of PTFE-based particles. The particle size can be measured by a laser scattering method in accordance with ISO13320-1 (1999-11-01).

The coating composition of the present disclosure comprises at least three components, for example, a solvent, a fluoropolymer which is soluble in the solvent (fluoropolymer A) and a fluoropolymer which is insoluble in the solvent (fluoropolymer B), but may optionally contain additives. Additives are commonly used in coating compositions to aid in preparation or to impart additional characteristics to the resulting composition. Preferable additives include, for example, surfactants, coloring agents having transparency, fluorescent dyes, whitening agents, anti-oxidants, and ultraviolet absorbers.

The coating composition of the present disclosure can be prepared by dissolving fluoropolymer A and optional additives in a solvent, and adding fluoropolymer B to the solution. The resulting coating solution has the desired viscosity and therefore can be coated on the surface of an article using conventional techniques such as brush coating, dip coating, or spray coating. In some cases, a sealing portion may be formed by dropping the coating solution in a predetermined portion using a technique such as potting. The coating solution may be coated by single or plural coating operations depending on the viscosity of the composition. However, since the viscosity may be adjusted by the addition of fluoropolymer B, a thick coating can be achieved in a single coating operation. The single coating operation may also reduce opacity caused by inclusion of air at the interface between layers in the case of multiple coating operations.

After the completion of coating, the resulting coating film is cured by drying. The drying operation may be performed at ambient temperature and, if necessary, drying may be accelerated using a heater or an oven.

The thickness of a coating film after drying, namely, a coating layer (or a sealing layer), with which the surface of an article is coated, varies depending on the amount of a coating solution and the number of coatings. The thickness of the coating layer is commonly at least about 10 μm (micrometer) and, for example, about 100 μm or more. Since fluoropolymer particles (fluoropolymer B) are added to the coating composition of the present disclosure, the thickness of the coating layer can be controlled to 0.5 mm (millimeter) or more, and particularly 1 mm or more, by a single coating operation.

The coating composition of the present disclosure has remarkable characteristics such as light transmission and/or diffusion, water resistance, ultraviolet stability, and coating ability. Therefore the coating composition of the present disclosure may be used to coat various articles, for example, to form a coating layer or a sealing layer. In particular, the coating layer or a sealing layer can be formed over a conductive portion of an article. The coating composition of the present disclosure can be used to coat an article, thereby sealing the conductive portion included in the article. Since the exposed portion (electric circuit, wiring, antenna, etc.) can be protected from moisture, ultraviolet light, or other surrounding adverse influences, the article including the conductive portion coated with the coating composition of this disclosure may be stably maintained for a long period of time. Further, use of the coating composition of this disclosure may also enable the downsizing of articles, such as traffic signaling devices, because sufficient water resistance can be achieved via the coating composition, eliminating the use of bulky housings, a hood or the like.

The present disclosure also provides an article comprising an object with a conductive portion, and a coating layer formed of the coating composition of the present disclosure wherein at least the conductive portion is sealed. The article of the present disclosure can include various objects with a conductive portion. Typical examples thereof include, but are not limited to:

an LED device in which an LED element of the LED device and a conductive portion connected to the LED element are at least sealed with the coating layer of the present disclosure,

a flexible circuit board comprising a functional element mounted on a surface (also referred to as a print circuit board) in which the functional element of the circuit board and a conductive portion connected to the functional element are at least sealed with the coating layer of the present disclosure,

an electronic device comprising a functional element installed therein in which the functional element of the device and a conductive portion connected to the functional element are at least sealed with the coating layer of the present disclosure,

a coated electric wire in which an exposed electric wire of the electric wire is at least sealed with the coating layer of the present disclosure, and

an antenna which is coated with the coating layer of the present disclosure.

Specific examples of use include, but are not limited to the following. The LED device includes, for example, a traffic signal device (for example, road signal device, railway signal device, construction signboard with signal lamp, etc.), an EL panel (for example, rise-and-fall type large-sized EL panels, information board, an on-vehicle traffic signal device, ringlight, etc.), a road traffic sign (for example, direction board, traffic jam display panel, guidance light for tunnel driving, etc.), an advertising medium (for example, large-sized LED television, advertising light, pole sign, internally illuminated EL signboard, channel letter, edge light, etc.) and an on-vehicle light.

The circuit board includes: a rigid print circuit board made of a phenol resin including cellulose, an epoxy resin including glass fibers or a fluororesin (PTFE, etc.); and a flexible print circuit board made of a polyimide resin or a hydrocarbon-based resin (PE, PP, etc.), an LED chip or a semiconductor chip being installed on the surface. Describing in more detail, in the flexible print circuit board, the base material is commonly formed of a flexible film, and can be formed of an acrylic resin, a polyester resin, a polyurethane resin, a polyvinyl chloride resin or a hydrocarbon-based resin, in addition to a polyimide resin. Also, the conductive portion such as wiring, circuit, and contact on the base material can be formed with an optional pattern using the same technique as that employed commonly to produce a print circuit board. For example, a wiring pattern layer such as wiring can be formed from a conductive metal such as copper, nickel, gold, silver or aluminum or an alloy thereof using a technique such as vacuum deposition or inkjet printing. Also, the wiring pattern layer may be formed by applying a conductor film on the entire surface of a film base material and selectively etching the conductor film. If necessary, the wiring pattern layer may be formed using a technique such as soldering.

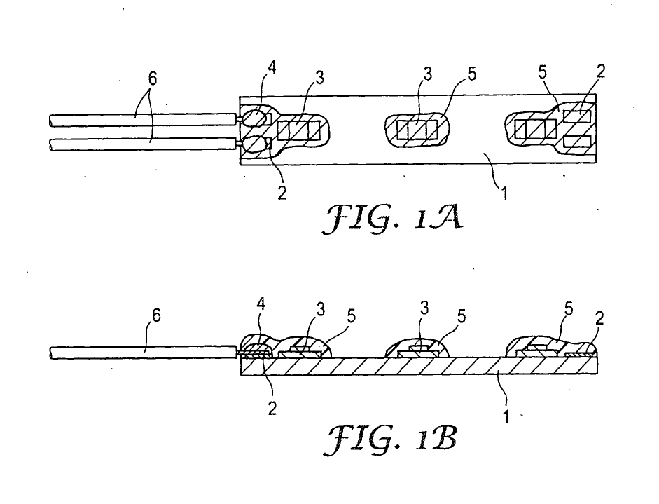

FIGS. 1 to 3 each show an example of a linear light comprising a circuit board comprising an LED chip installed therein. In a plan view of the respective drawings, a coating layer 5 is shown in a hatched line so as to help an understanding of the arranged state.

FIG. 1 shows a linear light in which an LED chip 3 is installed on a surface of a circuit board 1 made of an epoxy resin including glass fibers. The LED chip 3 can emit white light. On the surface of circuit board 1, a copper wiring 2 is exposed and a covered lead wire 6 is connected to the copper wiring and is fixed using solder 4. The copper wiring 2 and the connection portion between the copper wiring 2 and the lead wire 6, and the LED chip 3 is scaled with the coating layer 5 so as to coat them. The coating layer 5 can be easily formed by dropping the coating composition of the present disclosure in a spot-like manner using a drop method and curing the coating composition. In the example shown in the drawing, the coating composition of the present disclosure is applied only to a portion, which must be coated, of the surface of the circuit board 1. Adhesion of the coating composition to the circuit board 1 is very high and the coating layer 5 does not peel off during use.

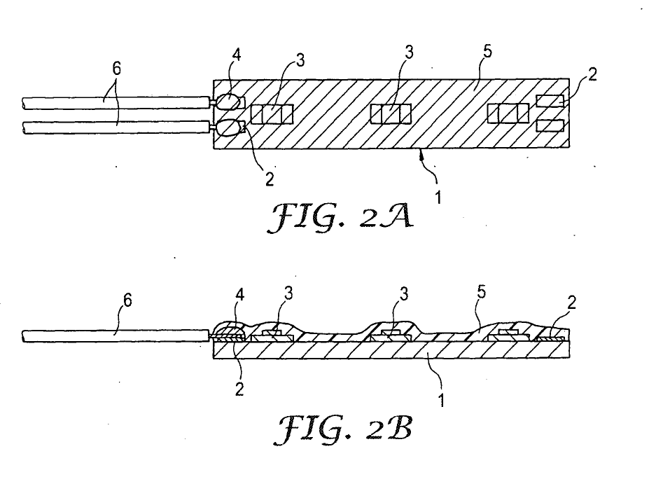

Water resistance, insulating properties, and durability of the circuit board can be further improved by coating the coating composition on the entire surface of one surface of the circuit board 1. FIG. 2 shows one modification of the circuit board shown in FIG. 1. In FIG. 2, the coating composition of the present disclosure is applied to the entire top surface of circuit board 1, including the LED chip 3. In this example, the coating composition can be applied by a spray-coating method. Adhesion of the coating composition to circuit board 1 is very high and the coating layer 5 does not peel off during use.

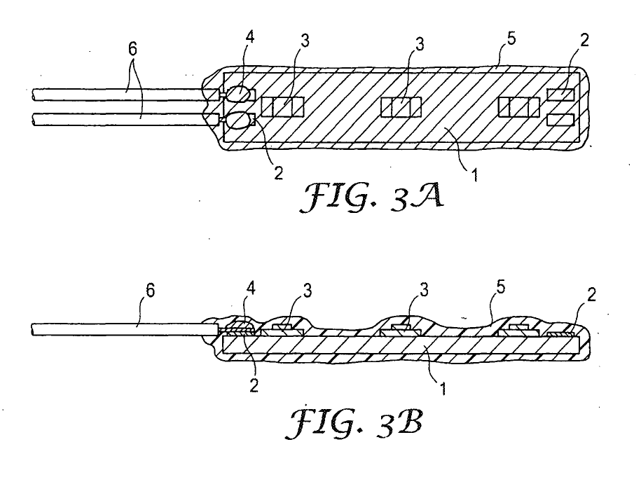

Water resistance, insulating properties, and durability of the circuit board can be further improved by coating the coating composition on the entire surface of the circuit board, and thus the range of the use of circuit board 1 can be further increased. FIG. 3 shows another modification of the circuit board 1 shown in FIG. 1. In FIG. 3, the coating composition of the present disclosure is uniformly coated on the entire surface (top, bottom, and sides) of the circuit board 1 to form a coating layer 5. In this example, the coating composition can be applied by a dip-coating method. Adhesion of the coating composition to the circuit board 1 is very high and the coating layer 5 does not peel off during use.

In addition, the coating composition of the present disclosure can be used to protect or seal an exposed portion of electric wire (not shown). For example, electric wire is commonly covered with a vinyl chloride resin. To use, the vinyl chloride resin is peeled away to a required position to expose the electric wire. The coating composition of the present disclosure can be used to coat the now exposed electric wire to protect the exposed electric wire from external influences (e.g., moisture). Similarly, the surface of various antennas can be coated with the coating composition of the present disclosure to protect the antennas. The antennas may be continuously used for a long period while maintaining excellent characteristics of the antenna without the occurrence of defects.

### EXAMPLES

The present disclosure will now be described by way of Examples. The present disclosure is not limited by these Examples.

### Example 1

In this example, the relationship between the viscosity and the drying time of the coating composition was examined based on the addition (or no addition) of fluoropolymer B.

Fluoroopolymer A, was a copolymer of TFE, HFP and VDF sold under the trade designation “DYNEON” THV 220A by Dyneon LLC, Oakdale, Minn. and MEK was used as a solvent. Fluoropolymer B, was a PTFE powder sold under the trade designation “DYNEON” Micropowder TF 9205 by Dyneon LLC., Oakdale, Minn. DYNEON THV 220A is a fluoropolymer having a molecular weight of more than 10,000. DYNEON Micropowder TF 9205 has an average particle size measured by a laser scattering method is 8 μm. With respect to coating compositions having various concentrations, the drying time and viscosity were measured.

### Method for Measurement of Drying Time

First, fluoropolymer A was added to the solvent at room temperature (25° C.) and dissolved by mixing to obtain a coating composition containing no fluoropolymer B. In the coating composition according to the present disclosure, fluoropolymer B was further added, followed by stirring to obtain a uniform dispersion solution.

In the experiments, 0.5 ml of the coating composition was spread over a horizontal glass plate in a shape of a circle having a diameter of about 30 mm (25 to 30 mm). The time that is required from the beginning of solidification of the coating composition coated on the surface of the plate to the time at which the liquid does not adhere to the finger when slightly touched, was taken as the surface drying time. Although, the coating would feel dry to the touch, there may still be fluid underneath the surface and the coating may feel elastic. The time, at which the coating no longer feels elastic, was recorded as the total drying time.

### Measurement of Viscosity

The viscosity of the coating composition was measured according to JISK6833 (fiscal 1994) using a viscometer manufactured by Tokyo Keiki Co., Ltd.

The composition, drying time, and viscosity of each component are summarized in Table 2 below.

TABLE 2

| Weight (%) of | Weight (%) of | | | |
|---|---|---|---|---|
| fluoropolymer | fluoropolymer | | | Viscosity |
| A based on | B based on | Surface | Total | of the |
| total weight of | weight of | drying | drying | coating |
| fluoropolymer | fluoropolymer | time | time | composition |
| A and MEK | A | (min) | (min) | (mPa · s) |
| 10 | 0 | 6.5 | 7.5 | 41 |
| 15 | 0 | 6.5 | 8.5 | 220 |
| 20 | 0 | 5.5 | 8.5 | 750 |
| 25 | 0 | 5.5 | 10.5 | 4,500 |
| 30 | 0 | 2.5 | 11.0 | 8,400 |
| 35 | 0 | 2.0 | 14.5 | 26,000 |
| 40 | 0 | 0.5 | 16.5 | 43,000 |
| 20 | 5 | 7.5 | 9.0 | 780 |
| 20 | 25 | 6.0 | 9.0 | 820 |
| 20 | 50 | 5.5 | 10.0 | 900 |
| 20 | 100 | 3.5 | 20.0 | 1,100 |
| 20 | 150 | 3.5 | 20.5 | 1,600 |
| 20 | 200 | 2.0 | 24.5 | 2,000 |

As shown in Table 2, when the viscosity of the coating composition was 4,000 mPa·s or more the surface drying time was less than 5.5 min. When the surface drying time is 3 minutes or less, it is nearly impossible to coat through brush coating.

As is apparent from the results shown in Table 2, in the coating composition containing no fluoropolymer B, even if the concentration of fluoropolymer A increases so as to form thick coating, the concentration of 25% by weight or more excessively increases the viscosity and excessively decreases the surface drying time, and thus a brush coating operation cannot be performed. On the other hand, in the coating composition of the present disclosure, proper viscosity and proper surface drying time can be maintained and thus a thick coating could be performed by a single coating operation. Also, by optimizing the viscosity, the thickness of the coating film can be increased so as to obtain a thick coating film in a single coating operation.

### Example 2

5 g of DYNEON TI-W 220A (fluoropolymer A) was added to 20 g of MEK and dissolved by mixing to obtain a 20% fluoropolymer A solution. To the resulting solution, 5 g of a ground product (classified into a powder having a particle size between 45 to 125 μm) of a different THV copolymer sold under the trade designation “DYNEON” THV 610 manufactured by Dyneon Co., Oakdale, Minn.) (fluoropolymer B) was added, followed by stirring to obtain a coating composition. This coating composition was dip coated onto a green copper substrate with drying three times. DYNEON THV 610 has a higher tetrafluoroethylene content than DYNEON THV 220A and is insoluble in MEK.

### Example 3

Example 3 was preformed in the same manner as Example 2, except that the particle size of DYNEON THV610 was classified as between 125 to 250 μm.

### Example 4

Example 4 was preformed in the same manner as Example 2, except that the particle size of DYNEON THV610 was classified as between 125 to 250 μm and butyl acetate was used in place of MEK as the solvent.

### Example 5

Example 5 was preformed in the same manner as in Example 2, except that fluoropolymer B was a PTFE fluorine resin particulate sold under the trade designation “DYNEON” TF9207 Micropowder (manufactured by 3M Co., St. Paul, Minn.) and butyl acetate was used in place of MEK as the solvent.

### Comparative Example 1

Comparative Example 1 was prepared in the same manner as in Example 2, except that 0.5 g (the same volume as that of 5 g of DYNEON THV 610) of glass bubbles sold under the trade designation “3M Glass Bubbles K20” (manufactured by 3M Co., St. Paul, Minn.) was added and a coating composition was prepared. The glass bubbles are a soda-lime borosilicate glass, with a true specific gravity of 0.200±0.02, and particle size distribution of 30 to 110 μm (80% or more).

### Comparative Example 2

Comparative Example 2 was prepared in the same manner as in Comparative Example 1, except that butyl acetate was used in place of MEK as the solvent.

### Comparative Example 3

Comparative Example 3 was prepared in the same manner as in Example 1, except that fluoropolymer B was not added.

### Comparative Example 4

Comparative Example 4 was prepared in the same manner as in Example 1, except that fluoropolymer B was not added and butyl acetate was used in place of MEK as the solvent.

The samples of the above Examples and Comparative Examples were subjected to a light transmission test and a water resistance test.

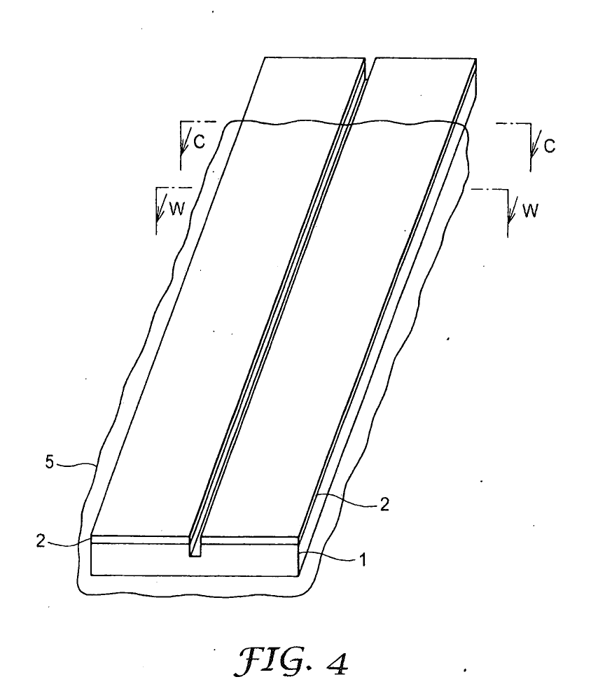

Measurement of transmittance: A film was peeled off from a paper phenol copper substrate and a spectral transmittance was measured over the entire visible range using a spectrophotometer, Model U-4100, manufactured by Hitachi, Ltd. Then a visible light transmittance was determined by correction of visibility and the light source.
Water resistance test: The paper phenol copper substrate used for coating had a width of 16 mm, thickness of 1.5 mm and a length of 75 mm and was provided with a slit having a width of 0.2 mm at the center (see FIG. 4). Therefore, right and left copper wirings 2 on substrate 1 were electrically independent. The entire portion below lines C-C was coated with a coating layer 5 formed by dip coating. Furthermore, a water resistance test was performed by dipping in water to lines W-W below the lines C-C. Each of the right and left portions, in which the upper copper wiring is exposed, was clipped with an alligator clip connected to a digital multimeter (P-10, manufactured by METEX Co.), and then a resistance value was measured. As shown in Table 3, a control sample having no coating layer showed a resistance value of several hundred kΩ (kilo ohms).

A sample having a coating layer that showed a resistance value of 40 MΩ or more when measured after 30 minutes in water (showing sufficient insulating properties and water resistance), was rated “Pass” in the water resistance test. The test results are shown in Table 3 below.

TABLE 3

| | Example | Example | Example | Example | Comparative | Comparative | Comparative | Comparative |
|---|---|---|---|---|---|---|---|---|
| | 2 | 3 | 4 | 5 | Example 1 | Example 2 | Example 3 | Example 4 |
| Fluoropolymer | THV220A | THV220A | THV220A | THV220A | THV220A | THV220A | THV220A | THV220A |
| A (g) | 5 g | 5 g | 5 g | 5 g | 5 g | 5 g | 5 g | 5 g |
| Fluoropolymer | THV 610 | THV 610 | THV 610 | TF9207 | K20 | K20 | none | none |
| B (g) | 5 g | 5 g | 5 g | 5 g | 0.5 g | 0.5 g | | |
| Fluoropolymer | 45-125 | 125-250 | 125-250 | about 4 | 30-110 | 30-110 | not added | not added |
| B particle size (μm) | | | | | | | | |
| Solvent (g) | MEK | MEK | Butyl | Butyl | MEK | Butyl | MEK | Butyl |
| | 20 g | 20 g | acetate | acetate | 20 g | acetate | 20 g | acetate |
| | | | 20 g | 20 g | | 20 g | | 20 g |
| Dry film | 0.58 | 0.77 | 0.73 | 0.65 | 0.60 | 0.75 | 0.23 | 0.23 |
| thickness (mm) | | | | | | | | |
| Light | 76 | 64 | 65 | 76 | 20 | 18 | 79 | 88 |
| transmittance (%) | | | | | | | | |
| Water | Pass | Pass | Pass | Pass | Pass | Pass | Pass | Pass |
| resistance | | | | | | | | |

As is apparent from the results shown in Table 3, thick coatings could be performed when fluoropolymer particles B were added and glass bubbles were added. Even when fluoropolymer particles B were added, almost the same light transmittance was achieved as when no fluoropolymer B was added. On the other hand, when glass bubbles were added, light transmittance was low and the coating film was whitened.

It is considered that transparency is obtained by similarity of a refractive index because the refractive index of DYNEON THV 220A is about 1.36, while the refractive index of a ground DYNEON THV610 and unground DYNEON TI-W 610 are about 1.36, and the refractive index of DYNEON TF9207 Micropowder is 1.35. On the other hand, since glass bubbles contain soda-lime borosilicate glass (refractive index: 1.53 to 1.57) as a main component, the difference in the refractive index between the DYNEON TF9207 Micropowder and DYNEON THV 220A is greater than 0.15 (for example, 0.17 to 0.21). Therefore, transparency of the dried coating composition could not be obtained.

### Example 6

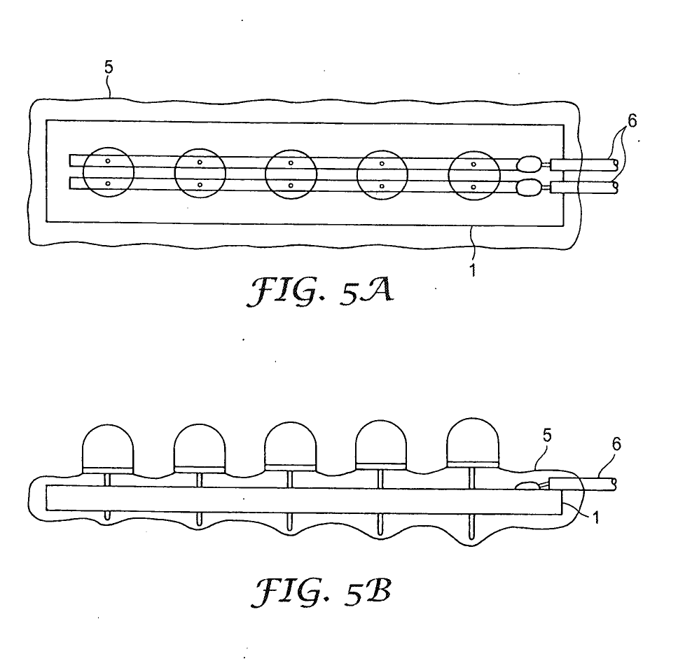

A coating composition of the present disclosure was prepared as described in Example 1 by adding the same amount by weight DYNEON TF9205 Micropowder to DYNEON THV220A to generate a coating composition in which the weight of fluoropolymer A based on the total weight of a fluoropolymer A and the solvent” is 20% and the weight of fluoropolymer B based on the weight of fluoropolymer A is 100%. This coating composition was coated onto circuit board 1 to form the article shown in FIG. 5. As shown in FIG. 5, LEDs are connected via electrical wires onto circuit board 1. Lead wire 6 is attached to circuit board 1 for connection to a power supply and a coating composition is applied to circuit board 1 to encase with coating layer 5. The bullet-shaped LEDs of the article shown in FIG. 5, were soldered onto circuit board 1. Because of the complicated shape, a dip coating method, a brush coating method and a potting method were used in combination to applying the coating composition to circuit board 1 comprising the LEDs. The length of the LED pins, which penetrate through, and protrude from, circuit board 1, varied from 1 to 5 mm. Even when the length of extruding pins was 5 mm, a thick coating could be performed with the coating compositions of the present disclosure. The resulting article (FIG. 5) was connected to a power supply and immersed in water. The LEDs emitted light continuously for 30 minutes or more. Neither the generation of oxygen and hydrogen gas (electrolysis) nor dissolution of metal ions was observed during the immersion in water.

### Example 7

A coating composition was prepared as disclosed in Example 6 and was coated onto an LED linear light (obtained under the trade designation “White LED Substrate Unit NP-00014”, manufactured by Shibazaki Seisakusho Ltd.) through dip coating and then the LED was continuously turned on by carrying an electric current for 2 hours or more in a state where the circuit board having an average thickness of 1,000 μm is immersed in water at a depth of 1 m from the water's surface. Consequently, it has been found that an LED installed circuit board of this example has water resistance corresponding to (Japanese Industrial Standard C0920) protection class 7 or higher class (immersion-proof type).

Foreseeable modifications and alterations of this invention will be apparent to those skilled in the art without departing from the scope and spirit of this invention. This invention should not be restricted to the embodiments that are set forth in this application for illustrative purposes.

1. A coating composition comprising a fluoropolymer A, a fluoropolymer B and a solvent, wherein the fluoropolymer A is soluble in the solvent, and the fluoropolymer B is granular and is insoluble in the solvent.

2. The coating composition according to claim 1 wherein a difference between a refractive index of the fluoropolymer A and a refractive index of the fluoropolymer B is less than 0.15.

3. The coating composition according to claim 1, wherein the fluoropolymer A is a fluoropolymer comprising at least hexafluoropropylene (HFP) and vinylidene fluoride (VdF).

4. The coating composition according to claim 1, wherein the fluoropolymer A is a fluoropolymer (THV) comprising at least tetrafluoroethylene (TFE), hexafluoropropylene (HFP) and vinylidene fluoride (VdF).

5. The coating composition according to claim 1, wherein the fluoropolymer B comprising a fluoropolymer selected from a fluoropolymer (THV) comprising at least tetrafluoroethylene (TFE), hexafluoropropylene (HFP) and vinylidene fluoride (VdF), a polytetrafluoroethylene (PTFE)-based fluoropolymer, a perfluoroalkoxyalkane (PFA)-based fluoropolymer, a perfluoroethylene-propene copolymer (FEP)-based fluoropolymer, an ethylene-tetrafluoroethylene copolymer (FTFE)-based fluoropolymer, a polyvinylidene fluoride (PVDF)-based fluoropolymer, a polychlorotrifluoroethylene (PCTFE)-based fluoropolymer, or an ethylene-chlorotrifluoroethylene copolymer (ECTFE)-based fluoropolymer.

6. The coating composition according to claim 1, which comprises the fluoropolymer B in an amount of 50 to 150% in terms of a dry weight of the fluoropolymer B in relation to a dry weight of the fluoropolymer A.

7. The coating composition according to claim 1, which is used to seal at least a conductive portion included in an article.

8. An article comprising a conductive portion, and a coating layer formed of the coating composition according to claim 1 with which at least the conductive portion is sealed.

9. The article according to claim 8, wherein the conductive portion is a portion exposed from the article.

10. The article according to claim 8, which is a LED device, and at least a LED element of the LED device and a conductive portion connected to the LED element are sealed with the coating layer.

11. The article according to claim 8, which is a flexible circuit board comprising a functional element mounted on a surface, and at least the functional element of the circuit board and a conductive portion connected to the functional element are sealed with the coating layer.

12. The article according to claim 8, which is an electronic device comprising a functional element installed therein, and at least the functional element of the device and a conductive portion connected to the functional element are sealed with the coating layer.

13. The article according to claim 8, which is a coated electric wire or antenna, and at least an exposed metal portion of the electric wire or antenna is sealed with the coating layer.
